(19) United States
(12) Patent Application Publication
(10) Pub. No.: US 2005/0002217 A1
(43) Pub. Date: Jan. 6, 2005

(54) Large volume storage device

(76) Inventors: Wen-Tsung Liu, Taipei (TW); Hsiang-An Hsieh, Taipei (TW)

Correspondence Address: Ann Tsai;Suite 137, PmB 174, 931 West 75th Street, Naperville, IL, 60565, US

(21) Appl. No.: 10/896,954

(22) Filed: Jul. 23, 2004

Related U.S. Application Data
(62) Division of application No. 10/244,022, filed on Sep. 16, 2002.

(51) Int. Cl. G11C 5/02

(52) U.S. Cl. 365/145

(57) ABSTRACT

A large volume storage device includes a circuit board, a power supply unit, storage media and a socket. The power supply unit is connected to the circuit board. The storage media is connected to the circuit board via a transmission interface. The socket has a shared container to hold and access a memory card. Once the memory card is inserted into the socket, the circuit board can convert instructions and control program of the memory card to those capable of being identified with the storage media and information can be transmitted to or backed up on the storage media.

The application is a divisional application of application Ser. No. 10/244,022.

### BACKGROUND OF THE INVENTION

1. Field of the Invention

The present invention relates to a large volume storage device.

2. Description of Related Art

As IT products are developed toward smallness, small flash memory cards (hereinafter is referred as small memory cards) are becoming popular in the market, in particular, Compact Flash Card (CF), Memory Stick Card (MS) and Secure Digital Card (SD). All above memory cards utilize silicon chips as the storage media and are connected to IT products or digital electronic devices through specific electric interfaces to store digital information. In addition, the small memory cards are small, light, power saving, shock resistance, large in volume, reliable and etc. They have been widely used in various digital IT devices, especially portable electronic devices, such as Digital Still Cameras (DSCs), Personal Digital Assistants (PDAs), Digital Music Players (DMPs), Digital Video Cameras (DVCs) and MP3 Players.

However, due to limitation of silicon chip, size and power consumption, the current small memory cards are not better than some of the traditional storage media in volume such as hard disks and CD-ROM drives. For instance, the maximum storage space of SD cards and MS cards are about 256 MB 128 MB respectively. In case of high density DSC products being used, each of the high density DSC products supports 6 million or more pixels but a SD card can only store 40˜70 photos and is unable to meet users' needs.

To solve the problem of the insufficient storage space of the forgoing small memory cards, the only way can be done by the user is to purchase multiple cards as reserves. However, the average ration of capacity/cost for the small memory cards is lower than that for some of the traditional storage media such that provision of additional cards gives the user a burden of more investment.

Hence, some of the manufacturers fabricate a hard disk associated with a control circuit board attached with a socket as a backup device for the small memory card. That is, when a small memory card is in use, the small memory card can be taken out from a digital electronic device and inserted into a small memory card backup device (usually a hard disk drive) to transmit or back up data in the small memory card to the device. As a result, the small memory card can be formatted again or original data can be deleted for further use.

Though the preceding small memory card backup device can solve the problem of insufficient storage space for the small memory card and it is not necessary for the user to buy so many small memory cards, it is inconvenient, complicated to operate the device and it is incapable of ensuring data transmission or backup. Consequently, data stored in the small memory cards become lost in case of problems occurring during the process of data transmission or backup and it results in serious trouble to the user.

### SUMMARY OF THE INVENTION

A main object of the present invention is to provide a large volume storage device with a memory card-adapting interface, which is connected to a digital electronic device, for storing or receiving digital information from the digital electronic device or transmitting information stored therein to the digital electronic device with facility such that it is capable of decreasing expense of large volume storage media significantly.

### BRIEF DESCRIPTION OF THE DRAWINGS

The present invention can be more fully understood in the following description with reference to accompanying drawings, in which:

FIG. 1 is a block diagram illustrating a preferred embodiment according to the present invention;

FIG. 2 is a circuit diagram according to the present invention in case of a SD card being inserted;

FIG. 3 is a circuit diagram according to the present invention in case of a MS card being inserted; and

FIGS. 4 and 5 are circuit diagrams according to the present invention in case of a CF card being inserted.

### DETAILED DESCRIPTION OF THE PREFERRED EMBODIMEN

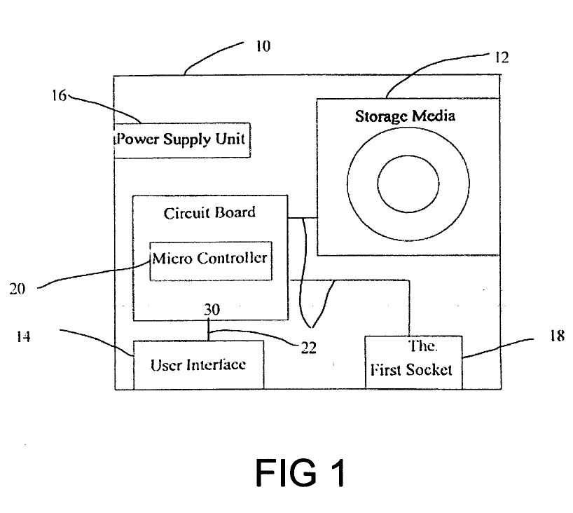

Referring to FIG. 1, a large volume storage device according to the present invention in the preferred embodiment thereof basically includes a circuit board 30, a power supply unit 16, a storage media 12 and a first socket 18.

The power supply unit 16 is connected to the circuit board 30 connected to the circuit board 30 with a built-in or external power supply. One or more batteries can be used as the power source. The storage media 12 is connected to the circuit board 39 via a transmission interface 22. The first socket 18 is connected to the circuit board 30 via the transmission interface 22 and can be received a memory card such as CF card, MS card or SD card.

Once the memory card is inserted into the first socket 18, the circuit board 30 can transform instructions and control program of the memory card so as to be identified by the storage media 12. Hence, information can be transmitted or backed up to the storage media 12.

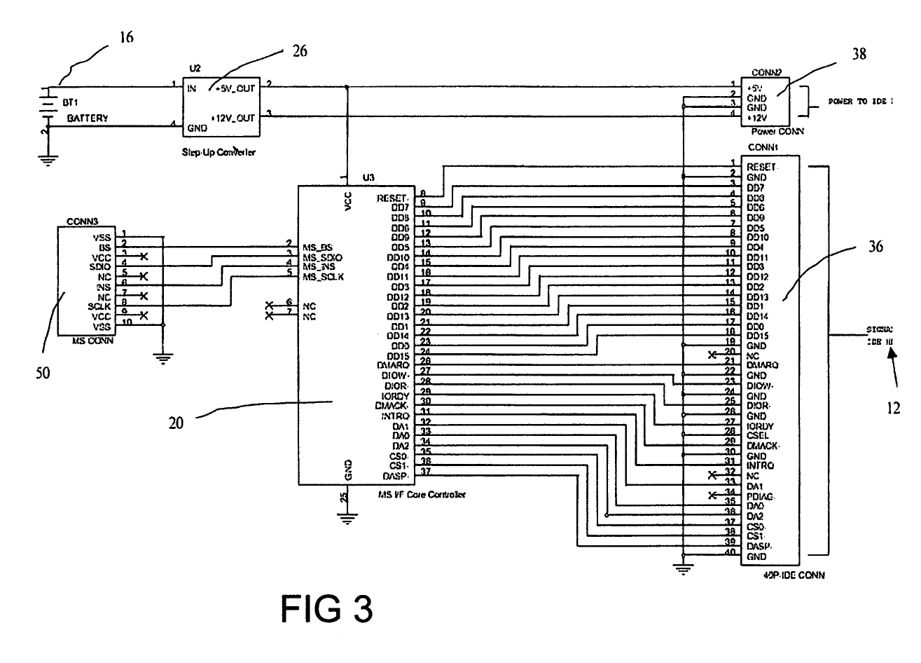

Moreover, the circuit board 30 has a micro controller 20 and a power conversion circuit (shown in FIGS. 3A and 3B). The power conversion circuit can transform power into internal voltage of the micro controller 20 and the storage media 12 with functions of over-current protection and voltage regulation. The micro controller 20 performs operations of detection, switching and control.

The storage media 12 can be a HDD, CD-RW, DVD-RW, DVD RAM, MO, ZIP or embedded flash memory card. The transmission interface in the larger volume storage device 10 supports IDE/ATA, IDE/ATAPI, USB or IEEE1394 interface.

In order to control operation of transmitting or backing up information in the memory card to the storage media 12, a user operation interface 14 can be provided in the large volume storage device 10 for the user being able to manage and control operations such as storing, browsing and deleting during the information being transmitted between the memory card and the storage media 12. Alternately, an interface cable (not shown) can be used for connecting the large storage device 10 to a personal computer to perform data transmission between the device and the personal computer.

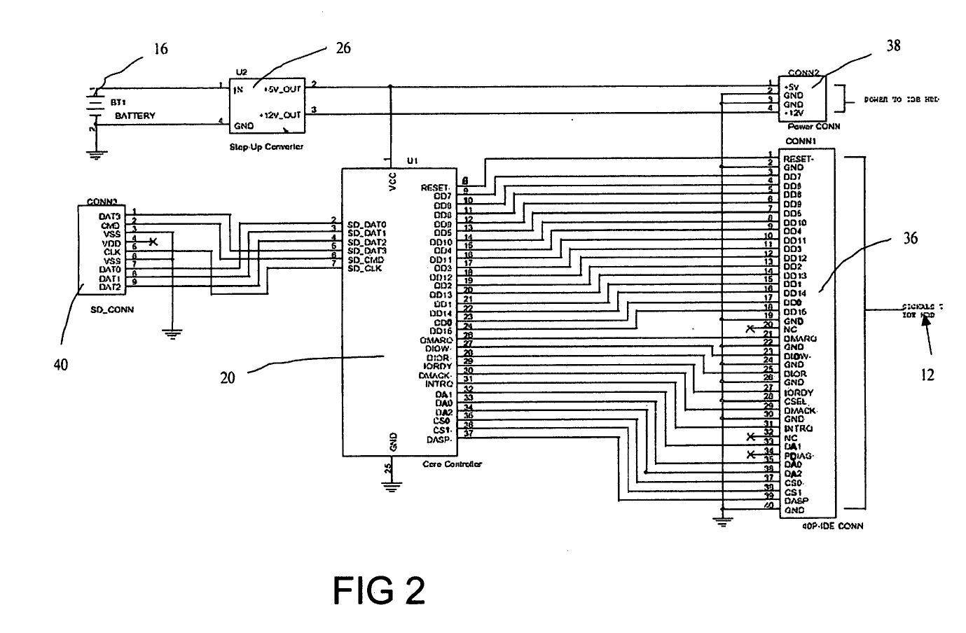

Referring to FIGS. 2 and 3, circuit utilized in the large volume storage device according to the present invention is illustrated. The circuit diagram shown is FIG. 2 is in a state of a SD card 40 being inserted and the circuit diagram shown in FIG. 3 is in a state of a MS card 50 being inserted. It can be seen a power supply unit 16, a micro controller 20, a power conversion circuit 26 are provided and a connector 36 or 38 is connected to a specific transmission interface, which is an IDE interface shown in the figures, The power conversion circuit 26 is provided with one or more batteries to convert power to +5V and +12V internally used in the micro controller 20 and the storage media 12 respectively. In case of the batteries being used up, they can be replaced with new batteries. Alternatively, the device can be connected to AC power supply directly. The power conversion circuit 26 provides functions of over-current protection and voltage regulation. The micro controller 20 performs functions such as detection, switching and control. The connector 36 or 38 is connected to the storage media 12 or the power supply unit 16.

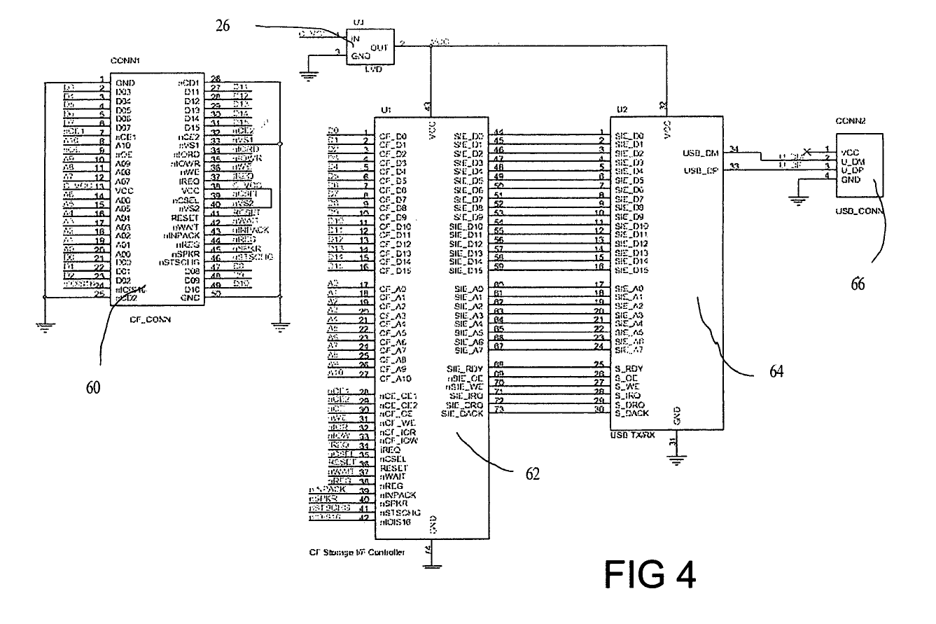

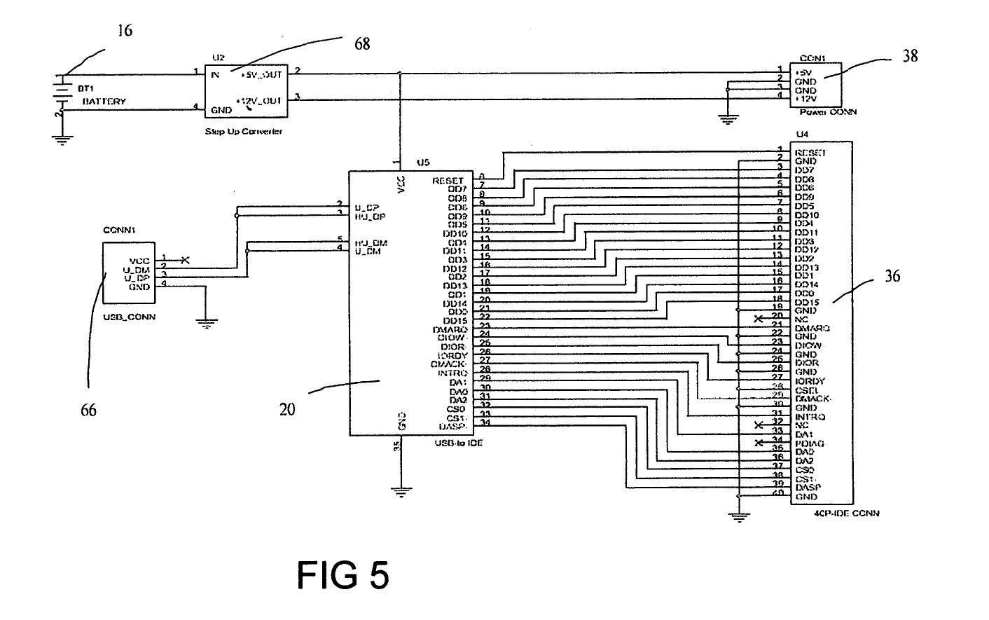

FIGS. 4 and 5 illustrate circuit diagrams for a CF card being inserted according to the present invention. A USB interface cable 24 is connected to the CF card 60 in the example. A CF controller 62, a USB controller 64 and a USB interface connector 66 are provided for the CF card 60 and the CF card 60 is connected to the storage media 12 via a USB interface signal cable 24. The power supply unit 16 supplies power to USB-IDE micro controller20 and IDE storage media 12 via a voltage boosting circuit 68. The USB interface connector 66 is connected to micro controller 20 on the circuit board so that standard instructions and communication protocol for USB interface to information identified by the IDE storage media 12 via the USB interface signal cable 24 and performing information mutual transmission the CF CARD and the digital electric device.

While the invention has been described with reference to a preferred embodiment, it is to be understood that modifications and variations may be easily made without departing from the spirit of this invention defined by the appended claim.

1. A large volume storage device, comprising:
a circuit board;
a power supply unit, being connected to the circuit board;
storage media, being connected to the circuit board via a transmission interface; and
a socket, having a shared container to hold and access a memory card;
whereby, once the memory card is inserted into the socket, the circuit board can convert instructions and control program of the memory card to those capable of being identified with the storage media and information can be transmitted to or backed up on the storage media.

2. The large volume storage device as defined in claim 1, wherein the circuit board has a micro controller and a power conversion circuit, which can transform power into internal voltages of the micro controller and the storage media with functions of over-current protection and voltage regulation, and the micro controller performs detection, switching and control.

3. The large volume storage device as defined in claim 1, wherein the storage media can be a HDD, an optical disk such as CD, DVD or MO, a diskette such as ZIP or a built-in flash memory.

4. The large volume storage device as defined in claim 1, wherein a user operation interface can be provided to for the user being capable of managing and controlling operations of information such as storing, browsing or deleting between the memory card and the storage media.

5. The large volume storage device as defined in claim 1, wherein the power supply unit can be built-in power supply unit with one or more batteries or an external power supply unit with AC power source.

6. The large volume storage device as defined in claim 1, wherein the memory card can be a CF, MS, or SD card.

7. The large volume storage device as defined in claim 1, wherein the interface can be an IDE/ATA, IDE/ATAPI, USB or IEEE 1394 interface.
